(19) United States
(12) Patent Application Publication
(10) Pub. No.: US 2026/0052763 A1
(43) Pub. Date: Feb. 19, 2026

(54) SEMICONDUCTOR DEVICES

(71) Applicant: SAMSUNG ELECTRONICS CO., LTD., Suwon-si (KR)

(72) Inventors: Byounghak Hong, Suwon-si (KR); Wookhyun Kwon, Suwon-si (KR); Younggwon Kim, Suwon-si (KR); Youngwoo Kim, Suwon-si (KR); Soojin Jeong, Suwon-si (KR); Seungseok Ha, Suwon-si (KR)

(21) Appl. No.: 19/046,240

(22) Filed: Feb. 5, 2025

(30) Foreign Application Priority Data
Aug. 16, 2024 (KR) 10-2024-0109747

(51) Int. Cl. H10D 84/83; H10D 30/00; H10D 30/01; H10D 62/10; H10D 62/13; H10D 62/83; H10D 62/832; H10D 62/834; H10D 64/23; H10D 64/66; H10D 84/01

(52) U.S. Cl. CPC H10D 84/832; H10D 30/506; H10D 62/102; H10D 62/121; H10D 62/151; H10D 62/83; H10D 62/832; H10D 62/834; H10D 64/256; H10D 64/665; H10D 84/83135; H10D 30/0191; H10D 84/014

(57) ABSTRACT

A semiconductor device includes a substrate including an active region extending in a first direction, gate structures extending in a second direction overlapping the active region, on the substrate, and spaced apart from each other in the first direction, a blocking gate structure overlapping the active region, between the gate structures, and extending in the second direction, source/drain regions disposed in a region in which the active region is recessed, on both sides of the blocking gate structure, a backside contact structure disposed below at least one of the source/drain regions, and backside blocking structures disposed below the gate structures and the blocking gate structure, respectively. The blocking gate structure includes a first element different from the gate structures.

### CROSS-REFERENCE TO RELATED APPLICATION(S)

This application claims the benefit under 35 USC 119(a) of Korean Patent Application No. 10-2024-0109747 filed on Aug. 16, 2024, in the Korean Intellectual Property Office, the entire disclosure of which is incorporated herein by reference for all purposes.

### BACKGROUND

The present disclosure relates to semiconductor devices.

As the demand for high performance, high speed, and/or multifunctionality of semiconductor devices increases, the integration of semiconductor devices is increasing. In accordance with the trend for high integration of semiconductor devices, semiconductor devices having a BackSide Power Delivery Network (BSPDN) structure in which power rails are placed on the backside of a wafer are being developed. In addition, efforts to develop semiconductor devices including FinFETs having a three-dimensional channel structure are being undertaken to reduce the limitations of operating characteristics due to the reduction in the size of planar metal oxide semiconductor FETs (MOSFETs).

### SUMMARY

Example implementations provide a semiconductor device with reduced process costs and process difficulty and improved reliability.

According to example implementations, a semiconductor device includes a substrate including an active region extending in a first direction; gate structures extending in a second direction overlapping the active region, on the substrate, and spaced apart from each other in the first direction; a blocking gate structure overlapping the active region, between the gate structures, and extending in the second direction; a plurality of channel layers surrounded by the blocking gate structure and the gate structures, respectively, on the active region, and spaced apart from each other in a third direction perpendicular to an upper surface of the substrate; source/drain regions in portions of the active region that are recessed, wherein the source/drain regions are on both sides of the blocking gate structure, and are connected to the plurality of channel layers; a first backside contact structure below a first source/drain region, wherein the first backside contact structure extends through the substrate and into the first source/drain region from a lower surface of the first source/drain region, wherein the first backside contact structure is electrically connected to the first source/drain region; and a plurality of backside blocking structures below the gate structures and the blocking gate structure, respectively, wherein the plurality of backside blocking structures extend through the substrate and the active region, and separate the active region. The blocking gate structure includes a first element different from the gate structures.

According to example implementations, a semiconductor device includes a substrate; a gate structure extending in a first direction on the substrate; a blocking gate structure adjacent to a first side of the gate structure, on the substrate, and extending in the first direction; a source/drain region between the gate structure and the blocking gate structure and in contact with the gate structure and the blocking gate structure; a backside contact structure extending into the substrate, and partially extending into the source/drain region from a lower surface of the source/drain region, wherein the backside contact structure is electrically connected to the source/drain region; and backside blocking structures including a first backside blocking structure below the blocking gate structure, extending through the substrate and in contact with the blocking gate structure, and a second backside blocking structure below the gate structure, extending through the substrate and in contact with a lower surface of the gate structure. A first transistor including the blocking gate structure is configured to exhibit a first threshold voltage and a second transistor including the gate structure is configured to exhibit a second threshold voltage. An absolute value of the first threshold voltage is greater than an absolute value of the second threshold voltage.

According to example implementations, a semiconductor device includes a substrate having a first region and second regions; a plurality of gate structures on the substrate; a plurality of source/drain regions, wherein each source/drain region is between adjacent gate structures of the plurality of gate structures; and a plurality of backside blocking structures, below the plurality of gate structures, respectively, wherein the plurality of backside blocking structures extend through the substrate and contact the plurality of gate structures, respectively. The plurality of gate structures include first gate structures spaced apart from each other in a first direction, on the first region, and extending in a second direction intersecting the first direction; second gate structures spaced apart from each other in the first direction and extending in the second direction, on the second region; a first blocking gate structure between the first gate structures, on the first region; and a second blocking gate structure between the second gate structures, on the second region. The first gate structures and the second blocking gate structure include a first element, and the second gate structures and the first blocking gate structure include a second element that is different from the first element.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor device according to example implementations;

FIGS. 2A to 2B are cross-sectional views illustrating a semiconductor device according to example implementations;

FIGS. 3A to 3B are cross-sectional views illustrating a semiconductor device according to example implementations;

FIG. 4 is a cross-sectional view illustrating a semiconductor device according to example implementations;

FIG. 5A is a plan view illustrating a semiconductor device according to example implementations;

FIG. 5B is a cross-sectional view illustrating a semiconductor device according to example implementations;

FIG. 6A is a plan view illustrating a semiconductor device according to example implementations;

FIGS. 6B and 6C are cross-sectional views illustrating a semiconductor device according to example implementations;

FIGS. 7A, 8A, 9, 10, 11A, 12A, 13A, 14A, and 15 are cross-sectional views illustrating a method of manufacturing a semiconductor device according to example implementations in accordance with a process sequence; and

FIGS. 7B, 8B, 11B, 12B, 13B, and 14B are cross-sectional views illustrating a method of manufacturing a semiconductor device according to example implementations in accordance with a process sequence.

### DETAILED DESCRIPTION

Hereinafter, example implementations will be described with reference to the attached drawings. Hereinafter, terms such as ‘on,’ ‘upper portion,’ ‘upper surface,’ ‘below,’ ‘lower portion,’ ‘lower surface,’ ‘side surface,’ and the like may be understood to refer to the drawings, unless otherwise explained.

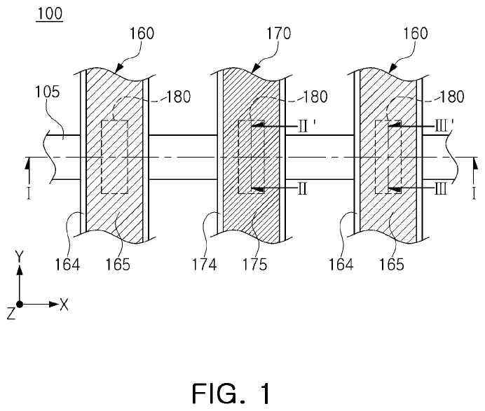

FIG. 1 is a plan view illustrating a semiconductor device according to example implementations. For convenience of explanation, only some components of the semiconductor device are illustrated in FIG. 1.

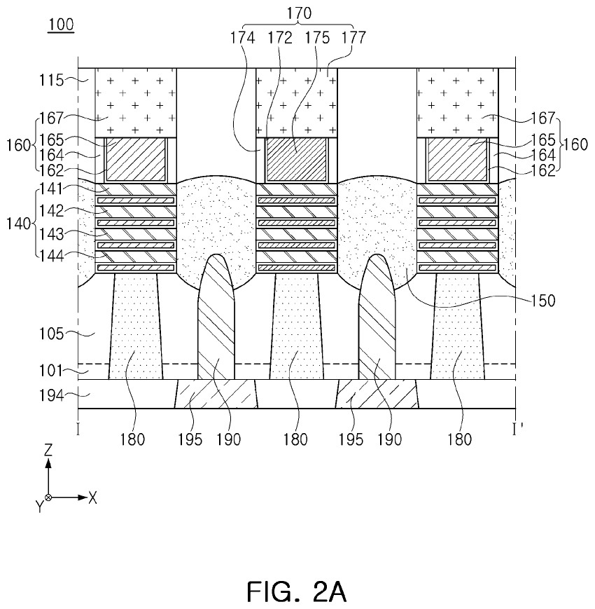

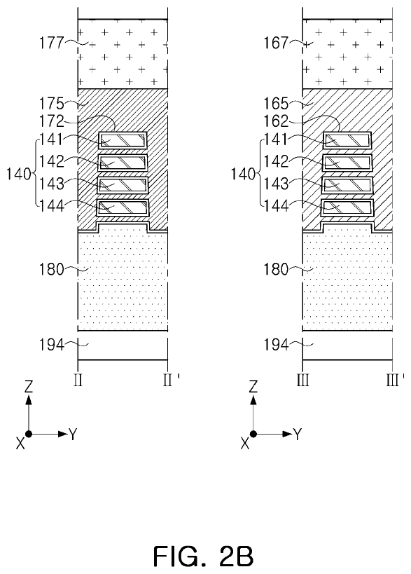

FIGS. 2A and 2B are cross-sectional views illustrating a semiconductor device according to example implementations. FIG. 2A illustrates a cross-section of the semiconductor device of FIG. 1 cut along the cutting line I-I,′ and FIG. 2B illustrates cross-sections of the semiconductor device of FIG. 1 cut along the cutting lines II-II′ and III-III′.

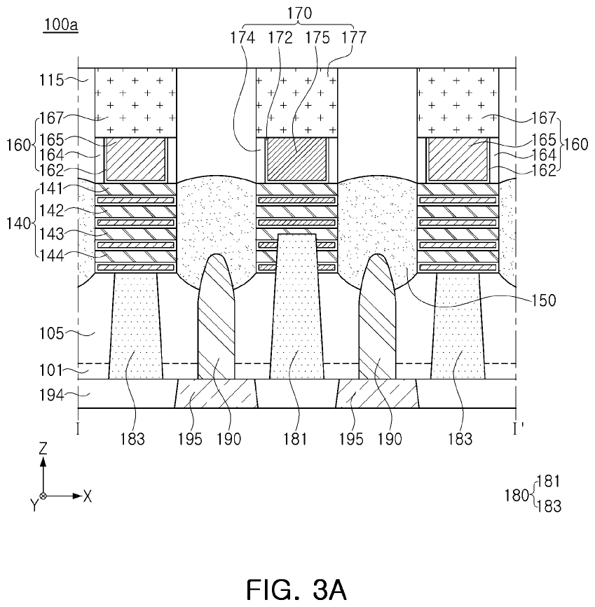

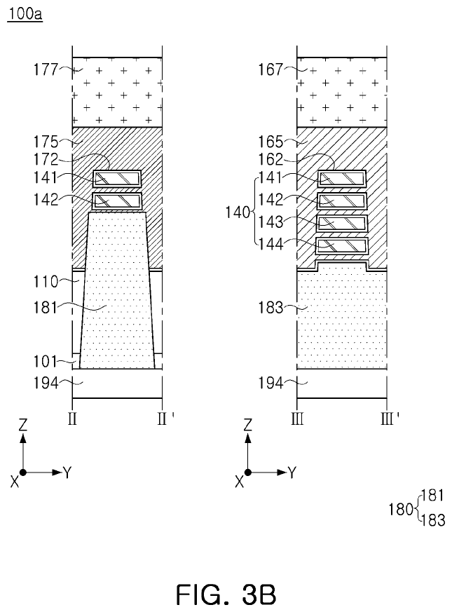

Referring to FIGS. 1 to 2B, a semiconductor device 100 may include a substrate 101 including an active region 105, channel structures 140 including first to fourth channel layers 141, 142, 143 and 144 disposed vertically and spaced apart from each other on the active regions 105, gate structures 160 extending while overlapping the active region 105 and each including a gate electrode 165, a blocking gate structure 170 extending while overlapping the active region 105, between the gate structures 160, and including a blocking gate electrode 175, source/drain regions 150 disposed between the blocking gate structure 170 and the gate structures 160 and in contact with the channel structures 140, backside blocking structures 180 respectively disposed below the gate structures 160 and the blocking gate structure 170, and backside contact structures 190 connected to the source/drain region 150. The semiconductor device 100 may further include an interlayer insulating layer 115, a backside insulating layer 194, and a backside power structure. Referring to FIG. 3B, the semiconductor device 100 may also include an element isolation layer 110.

In the semiconductor device 100, the active regions 105 may have a fin structure, and the gate electrodes 165 may be disposed between the active region 105 and the channel structure 140, between the first to fourth channel layers 141, 142, 143 and 144 of the channel structure 140, and on the channel structure 140. Accordingly, the semiconductor device 100 may include transistors of a Multi Bridge Channel FET (MBCFET™) structure, which is a gate-all-around type field effect transistor.

The substrate 101 may have an upper surface extending in the X-direction and the Y-direction. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, or a semiconductor on insulator (SeOI) layer.

The substrate 101 may include an active region 105 disposed in the upper portion thereof. The active region 105 is defined by an element isolation layer 110 within the substrate 101 and may be disposed to extend in a first direction, for example, an X-direction. However, depending on the description method, it may also be possible to describe the active region 105 as a separate configuration from the substrate 101. The active region 105 may partially protrude above the element isolation layer 110, so that the upper surface of the active region 105 may be located at a higher level than the upper surface of the element isolation layer 110. The active region 105 may be formed as a part of the substrate 101, or may include an epitaxial layer grown from the substrate 101. However, on both sides of the blocking gate structure 170, the active region 105 may be partially recessed to form recessed regions, and source/drain regions 150 may be disposed in the recessed regions.

In example implementations, the active region 105 may or may not include a well region containing impurities. For example, in the case of an n-type transistor (nFET), the well region may include p-type impurities such as boron (B), gallium (Ga), or indium (In). In the case of a p-type transistor (pFET), the well region may include n-type impurities such as phosphorus (P), arsenic (As), or antimony (Sb), and the well region may be located at a predetermined depth from the upper surface of the active region 105, for example.

Referring to FIG. 3B together, the element isolation layer 110 that the semiconductor device 100 may include may define an active region 105 on the substrate 101. The element isolation layer 110 may be formed, for example, by a shallow trench isolation (STI) process. The element isolation layer 110 may expose at least the upper surfaces of the active region 105, and may also expose a portion of the upper surface. The element isolation layer 110 may have a curved upper surface so that it has a higher level as it approaches the active region 105. The element isolation layer 110 may be formed of an insulating material. The element isolation layer 110 may be, for example, an oxide, a nitride, or a combination thereof.

The gate structures 160 may be disposed to extend in one direction, for example, in the Y-direction, on the active region 105. Channel regions of transistors may be formed in the channel structures 140 overlapping the gate electrodes 165 of the gate structures 160. The gate structures 160 may be disposed to be spaced apart from each other in the X-direction. Each of the gate structures 160 may include gate dielectric layers 162, gate spacer layers 164, a gate electrode 165, and a gate capping layer 167.

The gate dielectric layers 162 may be disposed between the active region 105 and the gate electrode 165 and between the channel structure 140 and the gate electrode 165, and may be disposed to cover at least a portion of the surfaces of the gate electrode 165. For example, the gate dielectric layers 162 may be disposed to surround all surfaces except the uppermost surface of the gate electrode 165. The gate dielectric layers 162 may extend between the gate electrode 165 and the gate spacer layers 164, but are not limited thereto. The gate dielectric layer 162 may include an oxide, a nitride, or a high-κ material. The high-κ material may mean a dielectric material having a higher dielectric constant than silicon oxide (SiO₂). The high-dielectric constant material may be, for example, any one of aluminum oxide (Al₂O₃), tantalum oxide (Ta₂O₃), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), and praseodymium oxide (HfAlₓO_{y}). According to example implementations, the gate dielectric layer 162 may be formed of a multilayer structure.

The gate electrode 165 may include a conductive material, for example, a metal nitride such as titanium nitride (TiN), tantalum nitride (TaN), or tungsten nitride (WN), and/or a metal material such as aluminum (Al), tungsten (W), or molybdenum (Mo), or a semiconductor material such as doped polysilicon. According to example implementations, the gate electrode 165 may be formed of a multilayer structure. The gate electrodes 165 may be connected to gate contact plugs disposed thereon. The gate electrodes 165 may include a p-type metal or an n-type metal depending on the conductivity type of the transistor. For example, in an n-type transistor, the gate electrodes 165 may include metals having a relatively small work function to facilitate operation of the transistor by reducing the threshold voltage of a transistor having a positive value, and these metals may be referred to as n-type metals. Conversely, in a p-type transistor, the gate electrodes 165 may include metals having a relatively large work function to facilitate operation of the transistor by reducing the absolute value of the threshold voltage of a transistor having a negative value, and these metals may be referred to as p-type metals.

The gate spacer layers 164 may be disposed on both sides of the gate electrode 165 on the channel structure 140. The gate spacer layers 164 may insulate the source/drain regions 150 and the gate electrodes 165. Depending on some example implementations, the shape of the upper portion of the gate spacer layers 164 may be variously changed, and the gate spacer layers 164 may be formed of a multilayer structure. The gate spacer layers 164 may include at least one of an oxide, a nitride, and an oxynitride, and may be formed of, for example, a low-κ film.

The gate capping layer 167 may be disposed on the gate electrode 165 and the gate spacer layers 164. In some implementations, the lower surface of the gate capping layer 167 may have a convex shape facing downward. The gate capping layer 167 may include an insulating material, and may include at least one of, for example, an oxide, a nitride, and an oxynitride.

A blocking gate structure 170 may be disposed between the gate structures 160. The blocking gate structure 170 may be disposed to extend in one direction, for example, the Y-direction, on the active region 105. The blocking gate structure 170 may include blocking gate dielectric layers 172, blocking gate spacer layers 174, blocking gate electrodes 175, and blocking gate capping layers 177, which may have configurations corresponding to the gate dielectric layers 162, the gate spacer layers 164, the gate electrodes 165, and the gate capping layers 167 of the gate structure 160, respectively. The blocking gate structure 170 may have a structure substantially the same as or similar to the gate structures 160, but may have a configuration including a different material from the gate structures 160. Except where otherwise described, the blocking gate dielectric layers 172, the blocking gate spacer layers 174, the blocking gate electrode 175, and the blocking gate capping layer 177 constituting the blocking gate structure 170 may have substantially the same or similar characteristics as the gate dielectric layers 162, the gate spacer layers 164, the gate electrode 165, and the gate capping layer 167, respectively.

The absolute value of the minimum voltage that should be applied to the blocking gate electrode 175 to allow current to flow in the channel structure 140 surrounded by the blocking gate structure 170 may be greater than the absolute value of the minimum voltage that should be applied to the gate electrode 165 to allow current to flow in the channel structure 140 surrounded by the gate structure 160. For example, the absolute value of the threshold voltage of the transistor including the blocking gate structure 170 may be greater than the absolute value of the threshold voltage of the transistor including the gate structure 160. Hereinafter, for convenience of explanation, the threshold voltage of the transistor including the blocking gate structure 170 is described as the first threshold voltage Vt1, and the threshold voltage of the transistor including the gate structure 160 is described as the second threshold voltage Vt2.

In some implementations, the semiconductor device 100 of FIGS. 1 to 2B may include an n-type transistor (nFET). In this case, the first threshold voltage Vt1 and the second threshold voltage Vt2 may have positive values, and the first threshold voltage Vt1 may be greater than the second threshold voltage Vt2. Accordingly, even if an operating voltage greater than the second threshold voltage Vt2 is applied to the gate electrodes 165 and the blocking gate electrode 175 to allow current to flow in the channel structures 140 surrounded by the gate structures 160, the operating voltage may be less than the first threshold voltage Vt1, and current may not flow in the channel structures 140 surrounded by the blocking gate structure 170. With this principle, in the operating voltage range of the gate electrodes 165, the source/drain regions 150 on both sides of the blocking gate structure 170 may be electrically isolated from each other.

In some nFET implementations, the blocking gate electrode 175 of the blocking gate structure 170 may include a material having a work function greater than that of the gate electrodes 165 of the gate structures 160. For example, the work function of the blocking gate electrode 175 may be greater than the work function of the gate electrodes 165. In some implementations, the gate electrodes 165 may include an n-type metal, and the blocking gate electrode 175 may include a p-type metal. Accordingly, the first threshold voltage Vt1 may be relatively shifted in a positive direction and may have a magnitude greater than the second threshold voltage Vt2. In some implementations, the blocking gate electrode 175 and the gate electrodes 165 may include different numbers of multilayer structures.

In some nFET implementations, the blocking gate dielectric layers 172 may include a different material from the gate dielectric layers 162. The blocking gate dielectric layers 172 may include a dipole-inducing material that causes the first threshold voltage Vt1 to shift in a positive direction. Accordingly, the first threshold voltage Vt1 may be shifted in a positive direction and may have a magnitude greater than the second threshold voltage Vt2.

In some nFET implementations, the blocking gate structure 170 may include a first element that is different from the gate structures 160, and in an nFET implementation, the first element may include materials that shift a threshold voltage of the transistor in a positive direction. For example, the first element may include at least one of aluminum (Al), tantalum (Ta), tungsten (W), manganese (Mn), chromium (Cr), ruthenium (Ru), platinum (Pt), gallium (Ga), germanium (Ge), and gold (Au). The first element may be included in at least one of the blocking gate electrode 175 and the blocking gate dielectric layers 172. In some nFET implementations, both the blocking gate structure 170 and the gate structure 160 include the first element, but the concentration of the first element included in the blocking gate structure 170 may be greater than the concentration of the first element included in the gate structure 160. In some nFET implementations, the gate structures 160 may include a second element that is different from the first element, and the second element may include materials that shift the threshold voltage of the transistor in the negative direction. For example, the second element may include at least one of lanthanum (La), gadolinium (Gd), ruthenium (Lu), yttrium (Y), and scandium (Sc). In some implementations, the first threshold voltage Vt1 may be 2 to 4 times the second threshold voltage Vt2. In some implementations, the difference between the first threshold voltage Vt1 and the second threshold voltage Vt2 may be 0.1 V to 0.5 V or 0.15 V to 0.25 V.

In some implementations, the semiconductor device 100 of FIGS. 1 to 2B may include a p-type transistor (pFET). In these cases, the first threshold voltage Vt1 and the second threshold voltage Vt2 may have negative values, and the first threshold voltage Vt1 may be smaller than the second threshold voltage Vt2. For example, the absolute value of the first threshold voltage Vt1 may be larger than the absolute value of the second threshold voltage Vt2. Accordingly, even if an operating voltage having an absolute value larger than the second threshold voltage Vt2 is applied to the gate electrodes 165 and the blocking gate electrode 175 to allow current to flow in the channel structures 140 surrounded by the gate structures 160, the absolute value of the corresponding operating voltage may be smaller than the absolute value of the first threshold voltage Vt1, and current may not flow in the channel structures 140 surrounded by the blocking gate structure 170. In this principle, in the operating voltage range of the gate electrodes 165, the source/drain regions 150 on both sides of the blocking gate structure 170 may be electrically isolated from each other.

In some pFET implementations, the blocking gate electrode 175 of the blocking gate structure 170 may include a material having a lower work function than the gate electrodes 165 of the gate structures 160. For example, the work function of the blocking gate electrode 175 may be lower than the work function of the gate electrodes 165. In some implementations, the gate electrodes 165 may include a p-type metal, and the blocking gate electrode 175 may include an n-type metal. Accordingly, the first threshold voltage Vt1 may be relatively shifted in the negative direction, so that the absolute value of the first threshold voltage Vt1 may have a larger magnitude than the absolute value of the second threshold voltage Vt2. In some implementations, the blocking gate electrode 175 and the gate electrodes 165 may include different numbers of multilayer structures. In some pFET implementations, the material used for the gate electrode 165 may be referred to as a p-type metal, and the material used for the blocking gate electrode 175 may be referred to as an n-type metal. In some implementations, the material used for the blocking gate electrode 175 of the pFET may be the same as the material used for the gate electrode 165 of the nFET.

In some pFET implementations, the blocking gate dielectric layers 172 may include a different material from the gate dielectric layers 162. The blocking gate dielectric layers 172 may include a dipole inducing material that causes the first threshold voltage Vt1 to shift in the negative direction. Accordingly, the first threshold voltage Vt1 shifts in the negative direction, so that the absolute value of the first threshold voltage Vt1 may have a larger magnitude than the absolute value of the second threshold voltage Vt2.

In some pFET implementations, to increase the absolute value of the first threshold voltage Vt1, the blocking gate structure 170 may include a first element different from the gate structures 160, and the first element may include materials that shift the threshold voltage of the transistor in the negative direction. In an example implementation, the first element may include at least one of lanthanum (La), gadolinium (Gd), ruthenium (Lu), yttrium (Y), and scandium (Sc). The first element may be included in at least one of the blocking gate electrode 175 and the blocking gate dielectric layers 172. In some pFET implementations, both the blocking gate structure 170 and the gate structure 160 include the first element, but the concentration of the first element included in the blocking gate structure 170 may be greater than the concentration of the first element included in the gate structure 160. In some implementations, the gate structures 160 may include a second element that is different from the first element, and in some pFET implementations, the second element may include materials that shift a threshold voltage of the transistor in a positive direction. For example, the second element may include at least one of aluminum (Al), tantalum (Ta), tungsten (W), manganese (Mn), chromium (Cr), ruthenium (Ru), platinum (Pt), gallium (Ga), germanium (Ge), and gold (Au). In some implementations, the first threshold voltage Vt1 may be two to four times the second threshold voltage Vt2. In some implementations, the difference between the first threshold voltage Vt1 and the second threshold voltage Vt2 may be 0.1 V to 0.5 V or 0.15 V to 0.25 V.

The semiconductor device 100 may electrically isolate adjacent transistors by the blocking gate structure 170. Since the absolute value of the first threshold voltage Vt1 is greater than the absolute value of the threshold voltage and the absolute value of the operating voltage of the surrounding transistors, adjacent transistors may be stably electrically isolated by the blocking gate structure 170 without introducing a separate configuration. Since the blocking gate structure 170 may be formed by a process substantially the same as or similar to the gate structures 160, the process cost may be reduced. In addition, the process difficulty in the back process may be reduced, thereby simplifying the process and improving the reliability of the semiconductor device.

The channel structures 140 may be disposed on the active region 105. The channel structures 140 may be surrounded by gate structures 160 and blocking gate structure 170. The channel structures 140 may include first to fourth channel layers 141, 142, 143 and 144, which are two or more channel layers spaced apart from each other in a direction perpendicular to an upper surface of the active region 105, for example, in the Z-direction, on the active region 105. The first to fourth channel layers 141, 142, 143 and 144 may be connected to the source/drain regions 150 while being spaced apart from the upper surface of the active regions 105. Unlike the channel structures 140 surrounded by the gate structures 160, the channel structure 140 surrounded by the blocking gate structure 170 may be a dummy channel structure 140 that does not form an electrical path. The first to fourth channel layers 141, 142, 143 and 144 may have a width that is the same as or similar to the active regions 105 in the Y-direction and a width that is the same as or similar to the gate structures 160 in the X-direction. In some implementations, the width of the first to fourth channel layers 141, 142, 143 and 144 in the Y-direction may decrease toward the lower channel layer. The number and shape of the channel layers 141, 142, 143 and 144 of each of the channel structures 140 may vary in example implementations. In some implementations, the semiconductor device 100 may have a FinFET structure that does not include a channel structure 140.

The first to fourth channel layers 141, 142, 143 and 144 may be formed of a semiconductor material, for example, at least one of silicon (Si), silicon germanium (SiGe), and germanium (Ge). The first to fourth channel layers 141, 142, 143 and 144 may be made of, for example, the same material as the substrate 101. According to example implementations, the first to fourth channel layers 141, 142, 143 and 144 may include an impurity region located in a region adjacent to the source/drain regions 150.

The source/drain regions 150 may be disposed on both sides of the blocking gate structure 170 to be in contact with the channel structures 140, respectively. The source/drain regions 150 may be disposed between the blocking gate structure 170 and the gate structures 160. The source/drain regions 150 may be disposed to cover side surfaces of the respective first to fourth channel layers 141, 142, 143, and 144 of the channel structure 140 in the X-direction. At least some of the source/drain regions 150 may be respectively connected to the backside contact structure 190 through the lower surfaces or the lower ends thereof. The source/drain region 150 connected to the backside contact structure 190 may have a shape recessed by the backside contact structure 190. In some implementations, the source/drain regions 150 may be disposed as dummy source/drain regions that are not connected to the backside contact structure 190. The upper surfaces of the source/drain regions 150 may be located at the same level as or higher than the lower surface of the gate electrode 165 on the channel structure 140, and the level may be variously changed in implementations.

The source/drain regions 150 may include at least one of a semiconductor material, for example, silicon (Si) and germanium (Ge), and may further include dopants, which are impurities. The dopants may include n-type dopants or the p-type dopants. For example, for an n-type transistor (nFET), the source/drain regions 150 may include n-type impurities such as phosphorus (P), arsenic (As), or antimony (Sb), and for a p-type transistor (pFET), the source/drain regions 150 may include p-type impurities such as boron (B), gallium (Ga), or indium (In). In some implementations, the source/drain regions 150 may include a plurality of epitaxial layers. The plurality of epitaxial layers may include different concentrations of germanium (Ge) or may include different concentrations of impurities. For example, the source/drain regions 150 may include a plurality of epitaxial layers that are sequentially stacked from the bottom, and the concentration of germanium (Ge) and/or the concentration of impurities may increase sequentially from the bottom.

In some implementations, the semiconductor device 100 may further include internal spacer layers that are disposed between the side surfaces of the source/drain regions 150 in the X-direction and the gate dielectric layers 162 and/or the blocking gate dielectric layers 172. The internal spacer layers may include an insulating material.

The backside blocking structures 180 may be disposed on the lowermost surfaces of the gate structures 160 and the blocking gate structure 170. The backside blocking structures 180 may penetrate the substrate 101 and the active region 105 to contact the gate structures 160 and the blocking gate structure 170, respectively, and may separate the active region 105. By the backside blocking structures 180, leakage current that may occur in the active region 105 under the gate structures 160 and the blocking gate structure 170 may be prevented. The backside blocking structures 180 may have a shape in which the width decreases as the level increases, but is not limited thereto. For example, in some implementations, the backside blocking structures 180 may have a shape in which the width increases and then decreases again as the level increases. In the second direction (for example, the Y-direction), the width of each of the backside blocking structures 180 may be equal to or greater than the width of the active region 105. The active region 105 extending in the first direction (for example, X-direction) may be separated by backside blocking structures 180. The backside blocking structures 180 may include an insulating material, for example, at least one of an oxide, a nitride, and an oxynitride.

The backside contact structures 190 may be disposed below the source/drain regions 150. The backside contact structures 190 may penetrate the substrate 101 and the active region 105 to be connected to the source/drain regions 150 and may apply an electrical signal to the source/drain regions 150. The backside contact structures 190 may partially recess the source/drain regions 150 from below and extend into the source/drain regions 150. The upper ends of the backside contact structures 190 may be located at a higher level than the upper ends of the backside blocking structures 180. The upper end of the backside contact structures 190 may be positioned at a level higher than the lower surface of the lowermost channel layer 144.

At least a portion of the side surface of the backside contact structures 190 may be inclined so that the width of the backside contact structures 190 increases as the level decreases. The backside contact structures 190 may include a metal material such as, for example, tungsten (W), cobalt (Co), molybdenum (Mo), copper (Cu), ruthenium (Ru), aluminum (Al), etc. The backside contact structures 190 may include a metal nitride such as, for example, a titanium nitride (TiN), a tantalum nitride (TaN), or a tungsten nitride (WN), or may include a metal such as, for example, titanium (Ti), cobalt (Co), molybdenum (Mo), or platinum (Pt). In an example implementation, the backside contact structures 190 may include a metal-semiconductor compound layer, such as a metal silicide layer, disposed at an interface with the source/drain regions 150.

The backside power structure 195 may be connected to the lower end or the lower surface of the backside contact structure 190. The backside power structure 195, together with the backside contact structure 190, may form a BSPDN that applies a power or ground voltage, and may also be referred to as a backside power rail or a buried power rail. In some implementations, the backside power structures 195 may be spaced from the backside blocking structures 180. For example, the backside power structure 195 may be a buried wiring line extending in one direction, such as the Y-direction, under the backside contact structure 190, but the shape of the backside power structure 195 is not limited thereto. For example, in some implementations, the backside power structure 195 may include a via region and/or a line region. In example implementations, the backside power structure 195 may be a buried wiring line extending in the X-direction. The width of the backside power structure 195 may increase continuously downward, but is not limited thereto. The backside power structure 195 may include at least one of a conductive material, such as tungsten (W), copper (Cu), aluminum (Al), cobalt (Co), ruthenium (Ru), titanium (Ti), and molybdenum (Mo).

The interlayer insulating layer 115 may cover the source/drain regions 150, the gate structures 160, and the blocking gate structure 170. The backside insulating layer 194 may cover the lower surface of the substrate 101, the lower surface of the backside blocking structure 180, and the lower surface of the backside contact structure 190 under the substrate 101. The interlayer insulating layer 115 and the backside insulating layer 194 may include at least one of an oxide, a nitride, and an oxynitride, and may include, for example, a low-κ material. According to example implementations, at least one of the interlayer insulating layer 115 and the backside insulating layer 194 may include multiple insulating layers.

The semiconductor device 100 may be packaged by flipping the structures of FIGS. 2A to 2B upside down so that the backside power structure 195 is positioned on top, but the packaging form of the semiconductor device 100 is not limited thereto.

In the description of the example implementations below, any description that overlaps with the description described above with reference to FIGS. 1 to 2B will be omitted.

FIGS. 3A and 3B are cross-sectional views illustrating a semiconductor device according to example implementations. FIG. 3A illustrates an area corresponding to FIG. 2A, and FIG. 3B illustrates an area corresponding to FIG. 2B.

Referring to FIGS. 3A and 3B, in a semiconductor device 100a, the backside blocking structures 180 may include a first backside blocking structure 181 positioned below a blocking gate structure 170 and second backside blocking structures 183 positioned below the respective gate structures 160. Unlike the semiconductor device 100 of FIGS. 2A and 2B, the first backside blocking structure 181 may recess the blocking gate structure 170 from below and extend into the interior of the blocking gate structure 170. The upper end of the first backside blocking structure 181 may be located at a higher level than the upper end of the second backside blocking structure 183. The upper end of the first backside blocking structure 181 may penetrate the lowermost channel layer 144. The level of the upper end of the first backside blocking structure 181 is not limited thereto. For example, the first backside blocking structure 181 may penetrate the third channel layer 143 and may be located at a higher level than the upper surface of the third channel layer 143. In some implementations, the first backside blocking structure 181 may also penetrate the first to fourth channel layers 141, 142, 143 and 144. In the second direction (for example, the Y-direction), the width of the first backside blocking structure 181 and the width of the second backside blocking structure 183 may be different. In FIG. 3B, the width of the second backside blocking structure 183 is illustrated as being larger, but is not limited thereto. In some implementations, the width of the first backside blocking structure 181 may be equal to or larger than the width of the second backside blocking structure 183.

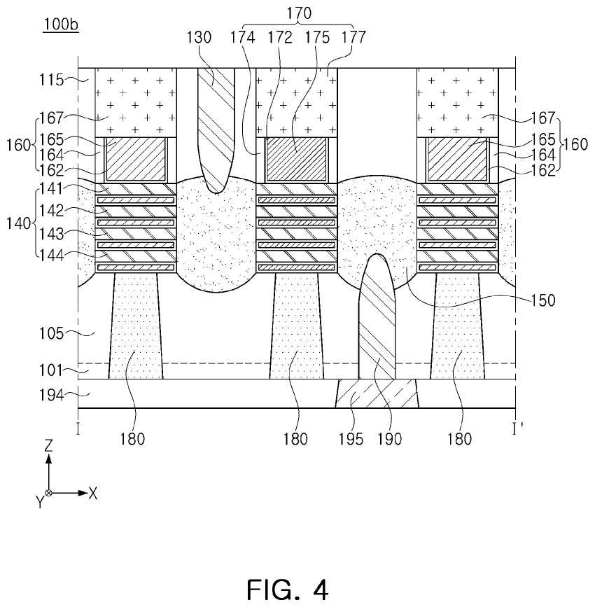

FIG. 4 is a cross-sectional view illustrating a semiconductor device according to example implementations. FIG. 4 illustrates an area corresponding to FIG. 2A.

Referring to FIG. 4, unlike the semiconductor device 100 of FIGS. 2A and 2B, some of the source/drain regions 150 of a semiconductor device 100b may not be connected to the backside contact structure 190, but may be connected to the frontside contact structure 130. The frontside contact structure 130 may be disposed to partially recess the source/drain region 150 from above by penetrating the interlayer insulating layer 115. The frontside contact structure 130 may have substantially the same or similar characteristics as the backside contact structure 190 except for the position at which it is disposed. The frontside contact structure 130 may include a metal material such as, for example, tungsten (W), cobalt (Co), molybdenum (Mo), copper (Cu), ruthenium (Ru), aluminum (Al), etc. The frontside contact structure 130 may include a metal nitride such as, for example, a titanium nitride (TiN) film, a tantalum nitride (TaN) film, or a tungsten nitride (WN) film, or may include a metal such as titanium (Ti), cobalt (Co), molybdenum (Mo), or platinum (Pt). In an example implementation, the frontside contact structure 130 may include a metal-semiconductor compound layer, such as a metal silicide layer, disposed at an interface with the source/drain regions 150.

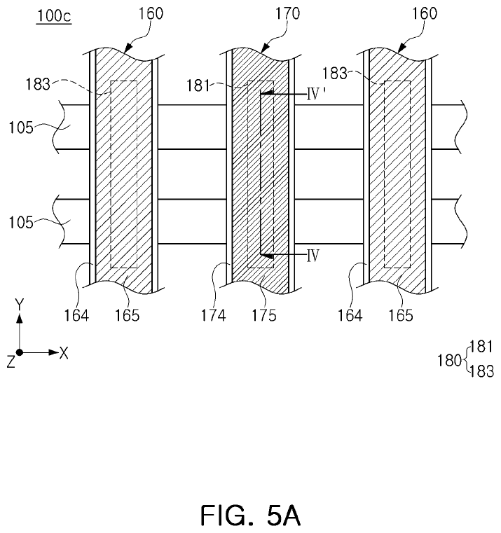

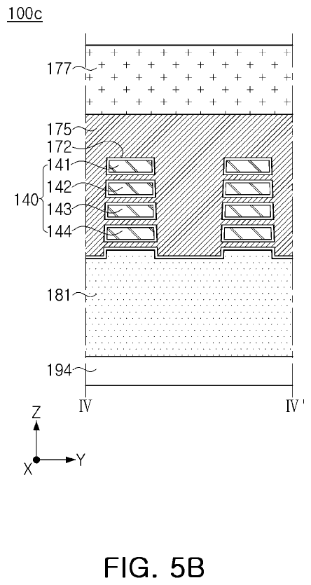

FIG. 5A is a plan view illustrating a semiconductor device according to example implementations. FIG. 5A illustrates an area corresponding to FIG. 1. For convenience of explanation, only some components of the semiconductor device are illustrated in FIG. 5A.

FIG. 5B illustrates a cross-section of the semiconductor device of FIG. 5A taken along the cutting line IV-IV'.

Referring to FIGS. 5A and 5B, a semiconductor device 100c may include active regions 105 disposed adjacently, and gate structures 160 and blocking gate structure 170 may extend to overlap the active regions 105. Unlike the semiconductor device 100 of FIGS. 2A and 2B, the backside blocking structures 180 may extend further in the second direction (for example, the Y-direction) to cut a plurality of active regions 105. In some implementations, the first backside blocking structure 181 under the blocking gate structure 170 may cut a plurality of active regions 105, while the second backside blocking structures 183 under the gate structures 160 may cut only one active region 105. Like the example implementations of the semiconductor device 100a of FIGS. 3A and 3B, the first backside blocking structure 181 may be disposed to partially recess the blocking gate structure 170 from the bottom, and the upper end of the first backside blocking structure 181 may be positioned at a higher level than the upper end of the second backside blocking structure 183. Depending on the design use, the form of the backside blocking structures 180 may be modified in various manners.

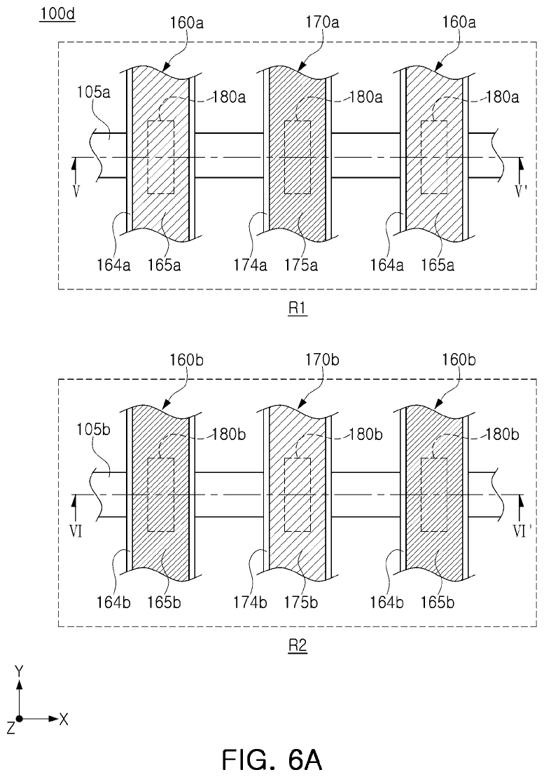

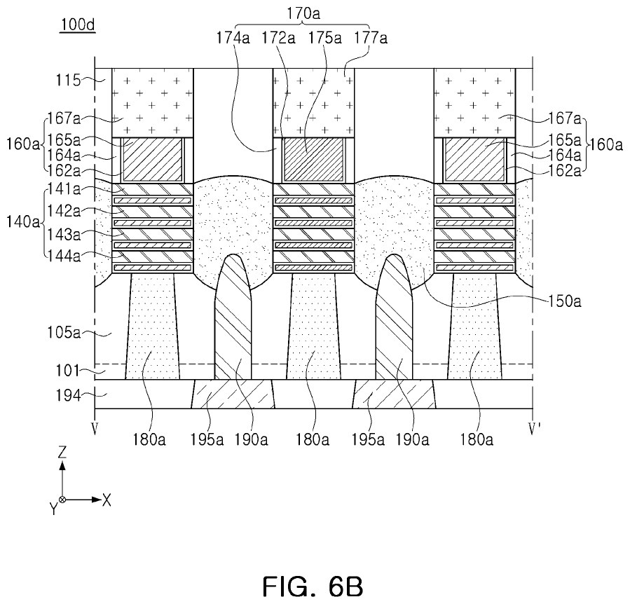

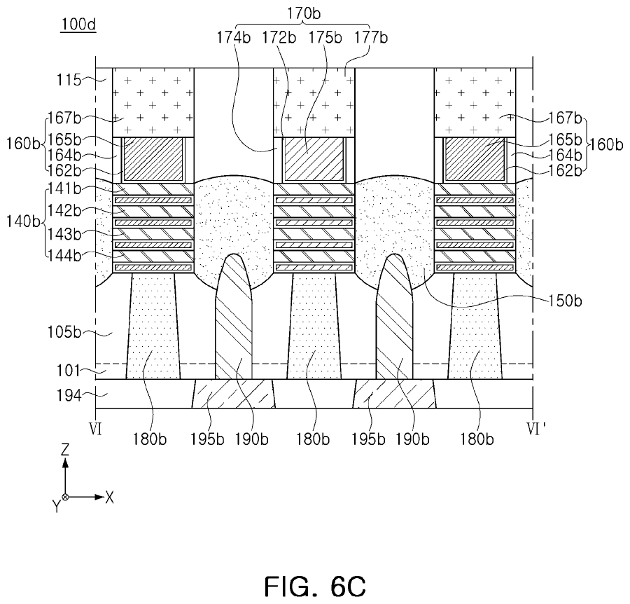

FIG. 6A is a plan view illustrating a semiconductor device according to example implementations. FIG. 6A illustrates regions corresponding to FIG. 1. For convenience of explanation, only some components of the semiconductor device are illustrated in FIG. 6A.

FIG. 6B illustrates a cross-section of the semiconductor device of FIG. 6A taken along a cutting line V-V,′ and FIG. 6C illustrates a cross-section of the semiconductor device of FIG. 6A taken along a cutting line VI-VI′.

Referring to FIGS. 6A to 6C, a semiconductor device 100d may include a first region R1 and a second region R2. The first region R1 and the second region R2 may be adjacent to each other or spaced apart from each other. The first region R1 and the second region R2 may be regions having different conductivity types. The first region R1 may configure a transistor of the first conductivity type, and the second region R2 may configure a transistor of the second conductivity type that is different from the first conductivity type. For example, the first region R1 may be an nFET region and the second region R2 may be a pFET region. Conversely, the first region R1 may be a pFET region and the second region R2 may be an nFET region. Hereinafter, example implementations in which the first region R1 is an nFET region and the second region R2 is a pFET region will be described.

In the first region R1, which is an nFET region, first gate structures 160a and first blocking gate structure 170a may be disposed, and in the second region R2, which is a pFET region, second gate structures 160b and second blocking gate structure 170b may be disposed. The first gate electrodes 165a and the second blocking gate electrode 175b may include an n-type metal having a relatively small work function, and the second gate electrodes 165b and the first blocking gate electrode 175a may include a p-type metal having a relatively large work function.

The first blocking gate structure 170a may include a first element that shifts the threshold voltage of the transistor in a positive direction, and the second blocking gate structure 170b may include a second element that shifts the threshold voltage of the transistor in a negative direction. The second gate structures 160b may include the first element, and the first gate structures 160a may include the second element. The first blocking gate structure 170a and the second gate structures 160b may be substantially the same structures and may be formed by substantially the same process. The second blocking gate structure 170b and the first gate structures 160a may be substantially the same structures and may be formed by substantially the same process. Since the first gate structures 160a include the second element and the first blocking gate structure 170a includes the first element in the first region R1, which is an nFET region, the threshold voltage of the transistor including the first blocking gate structure 170a shifts in the positive direction and the threshold voltage of the transistor including the first gate structures 160a shifts in the negative direction, so that the difference between these threshold voltages may increase. Accordingly, in an operating voltage range that generates current in the channel structures 140 surrounded by the first gate structures 160a, current may be blocked in the channel structures 140 surrounded by the first blocking gate structure 170a. This principle may also be applied to the second gate structures 160b and the second blocking gate structure 170b in the second region R2, which is the pFET region.

Accordingly, the semiconductor device 100d may include a structure that electrically isolates the peripheral components in each region without a separate additional process by forming the first blocking gate structure 170a and the second gate structures 160b with the same configuration, and forming the second blocking gate structure 170b and the first gate structures 160a with the same configuration. Accordingly, the process cost and process difficulty may be reduced, and a semiconductor device with improved reliability may be provided.

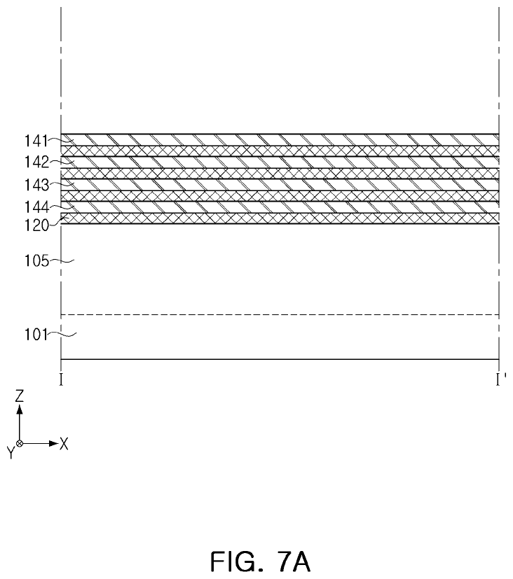

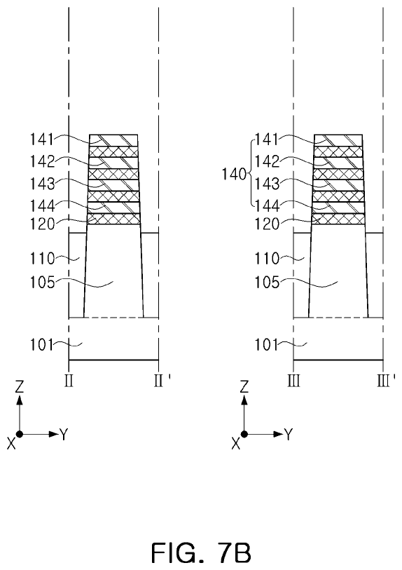

FIGS. 7A to 15 are drawings illustrating a method of manufacturing a semiconductor device according to example implementations in accordance with the process sequence.

FIGS. 7A, 8A, 9, 10, 11A, 12A, 13A, 14A, and 15 illustrate cross-sections corresponding to FIG. 2A.

FIGS. 7B, 8B, 11B, 12B, 13B, and 14B illustrate cross-sections corresponding to FIG. 2B.

Referring to FIGS. 7A and 7B, sacrificial layers 120 and first to fourth channel layers 141, 142, 143 and 144 are alternately stacked on a substrate 101, and the sacrificial layers 120, the first to fourth channel layers 141, 142, 143 and 144, and the substrate 101 are partially removed to form an active structure including an active region 105.

The substrate 101 may include silicon (Si), germanium (Ge), or silicon germanium (SiGe). The substrate 101 may include a bulk wafer, an epitaxial layer, a silicon on insulator (SOI) layer, or a semiconductor on insulator (SeOI) layer.

The sacrificial layers 120 may be layers that are replaced with gate dielectric layers 162 and gate electrodes 165, and blocking gate dielectric layers 172 and blocking gate electrodes 175 through subsequent processes, as illustrated in FIGS. 2A and 2B. The sacrificial layers 120 may be formed of a material having etch selectivity with respect to the first to fourth channel layers 141, 142, 143 and 144, respectively. The first to fourth channel layers 141, 142, 143 and 144 may include a different material from the sacrificial layers 120. The sacrificial layers 120 and the first to fourth channel layers 141, 142, 143 and 144 may include a semiconductor material including at least one of, for example, silicon (Si), silicon germanium (SiGe), and germanium (Ge), but may include different materials, and may or may not include impurities. For example, the sacrificial layers 120 may include silicon germanium (SiGe), and the first to fourth channel layers 141, 142, 143 and 144 may include silicon (Si).

The sacrificial layers 120 and the first to fourth channel layers 141, 142, 143 and 144 may be formed by performing an epitaxial growth process from the substrate 101. The number of layers of the channel layers 141, 142, 143 and 144 alternately stacked with the sacrificial layers 120 may vary in some implementations.

The active structure may include an active region 105, sacrificial layers 120, and the first to fourth channel layers 141, 142, 143 and 144. The active structure may be formed in a line shape extending in one direction, for example, the X-direction. The side surfaces of the active structure along the Y-direction may be coplanar with each other and may be positioned on a straight line.

In the area where the active region 105, the sacrificial layers 120, and respective portions of the first to fourth channel layers 141, 142, 143 and 144 are removed, an insulating material may be filled, and then an element isolation layer 110 may be formed by removing a portion of the insulating material so that the active region 105 protrudes. The upper surface of the element isolation layer 110 may be formed lower than the upper surface of the active region 105.

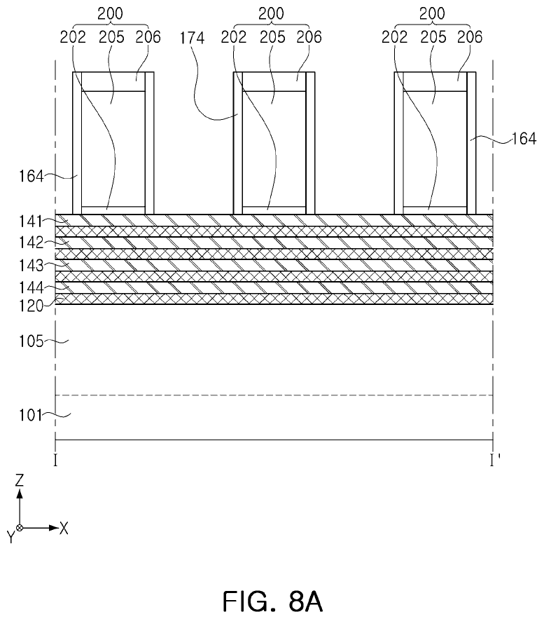

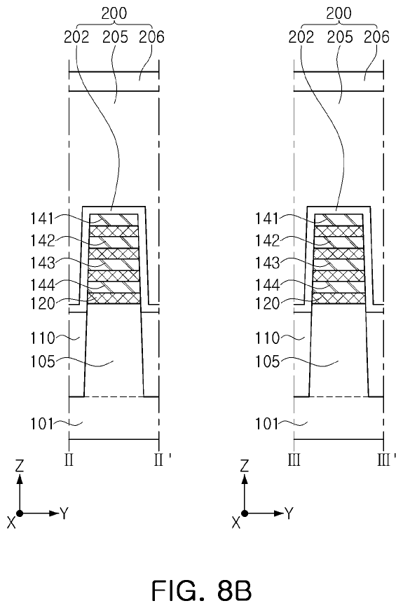

Referring to FIGS. 8A and 8B, sacrificial gate structures 200, gate spacer layers 164, and blocking gate spacer layers 174 may be formed on the active structure.

Each of the sacrificial gate structures 200 may be a sacrificial structure formed in an area where gate dielectric layers 162 and a gate electrode 165, and blocking gate dielectric layers 172 and a blocking gate electrode 175 are disposed, on the channel structure 140, through a subsequent process, as illustrated in FIGS. 2A and 2B. The sacrificial gate structures 200 may have a line shape extending in one direction while overlapping the active structure. The sacrificial gate structures 200 may extend, for example, in the Y-direction.

Each of the sacrificial gate structures 200 may include first and second sacrificial gate layers 202 and 205 and a mask pattern layer 206, sequentially stacked. The first and second sacrificial gate layers 202 and 205 may be patterned using the mask pattern layer 206. The first and second sacrificial gate layers 202 and 205 may be an insulating layer and a conductive layer, respectively, but are not limited thereto, and the first and second sacrificial gate layers 202 and 205 may be formed as a single layer. For example, the first sacrificial gate layer 202 may include silicon oxide, and the second sacrificial gate layer 205 may include polysilicon. The mask pattern layer 206 may include silicon oxide and/or silicon nitride.

Gate spacer layers 164 may be formed on both sidewalls of sacrificial gate structures 200 positioned in an area where gate structures 160 are to be formed, and blocking gate spacer layers 174 may be formed on both sidewalls of sacrificial gate structures 200 positioned in an area where blocking gate structure 170 are to be formed. The gate spacer layers 164 and the blocking gate spacer layers 174 may be formed of a low-κ material and may include, for example, at least one of SiO, SiN, SiCN, SiOC, SiON, and SiOCN.

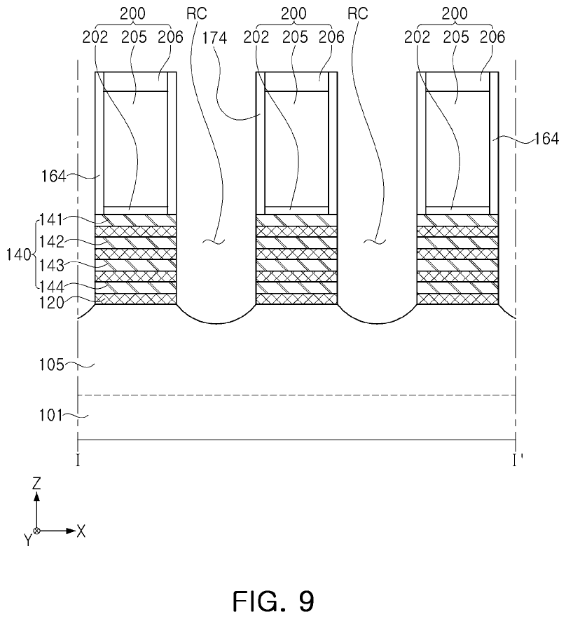

Referring to FIG. 9, the sacrificial layers 120 and the first to fourth channel layers 141, 142, 143 and 144 exposed by the sacrificial gate structures 200 may be partially removed to form recess regions (RC).

By using the sacrificial gate structures 200, the gate spacer layers 164, and the blocking gate spacer layers 174 as masks, the exposed sacrificial layers 120 and a portion of the first to fourth channel layers 141, 142, 143 and 144 may be removed, and the active regions 105 may be partially removed to form recess regions (RC). As a result, the first to fourth channel layers 141, 142, 143 and 144 may form channel structures 140 having a limited length along the X-direction.

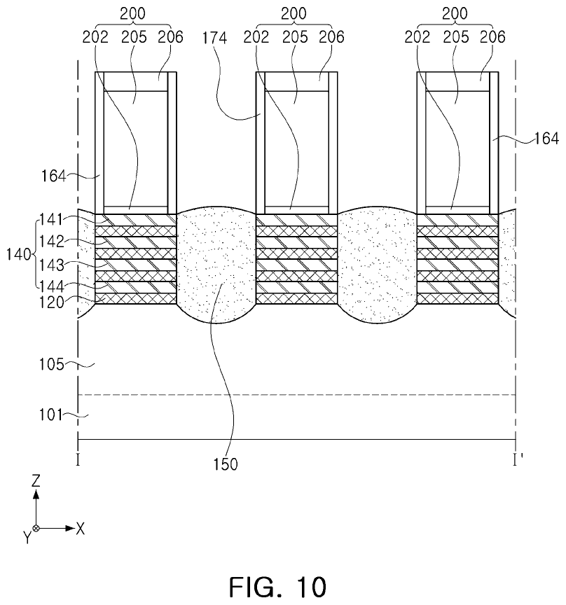

Referring to FIG. 10, source/drain regions 150 may be formed in the recess regions (RC).

The source/drain regions 150 may be formed by growing from the side surfaces of the channel structures 140 and the active regions 105, and the sacrificial layers 120, for example, by a selective epitaxial process. In some implementations, the source/drain regions 150 may include impurities by in-situ doping. Each of the source/drain regions 150 may include a plurality of epitaxial layers. The multiple epitaxial layers may have different concentrations of non-silicon elements.

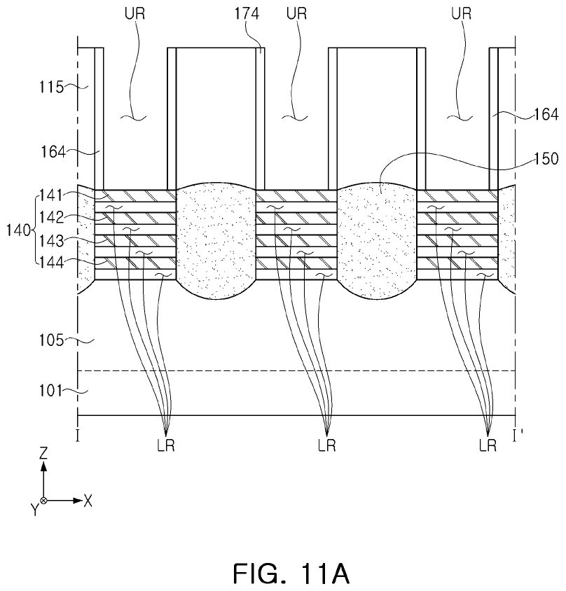

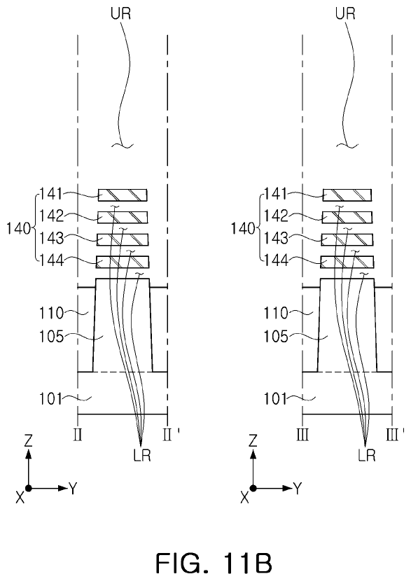

Referring to FIGS. 11A and 11B, an interlayer insulating layer 115 may be formed, and the sacrificial layers 120 and the sacrificial gate structures 200 may be removed.

The interlayer insulating layer 115 may be formed by forming an insulating film covering the sacrificial gate structures 200 and the source/drain regions 150 and performing a planarization process.

The sacrificial layers 120 and the sacrificial gate structures 200 may be selectively removed with respect to the gate spacer layers 164, the blocking gate spacer layers 174, the interlayer insulating layer 115, the source/drain regions 150, and the channel structures 140. First, the sacrificial gate structure 200 may be removed to form an upper gap region (UR), and then the sacrificial layers 120 exposed through the upper gap region (UR) may be removed to form lower gap regions (LR). For example, when the sacrificial layers 120 include silicon germanium (SiGe) and the channel structures 140 include silicon (Si), the sacrificial layers 120 may be selectively removed by performing a wet etching process.

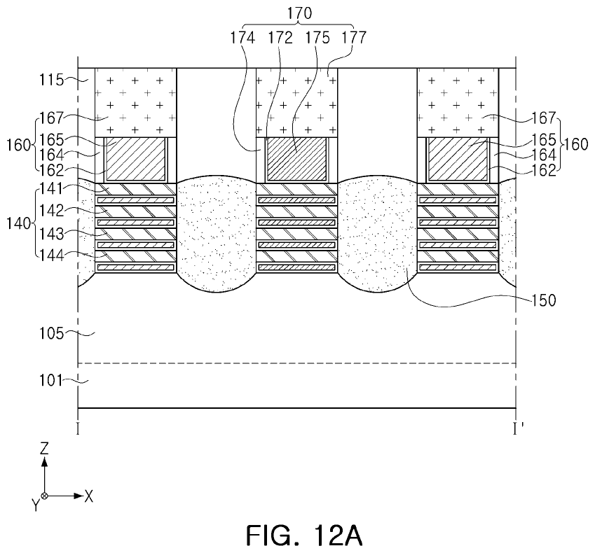

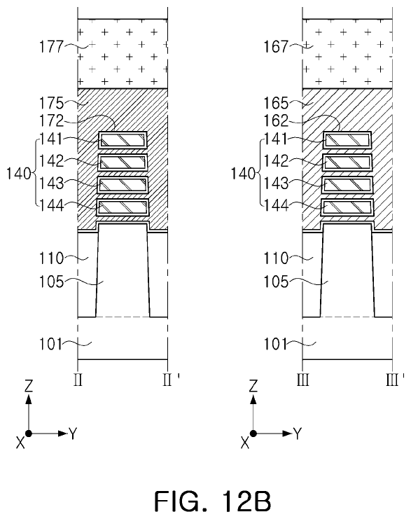

Referring to FIGS. 12A and 12B, gate structures 160 and blocking gate structure 170 may be formed.

Gate dielectric layers 162 and gate electrodes 165, and blocking gate dielectric layers 172 and blocking gate electrodes 175 may be formed to fill upper gap regions (UR) and lower gap regions (LR). The gate dielectric layers 162 and blocking gate dielectric layers 172 may be formed to conformally cover inner surfaces of the upper gap regions (UR) and lower gap regions (LR). The gate dielectric layers 162 and blocking gate dielectric layers 172 may be formed simultaneously, but an annealing process may be performed to selectively inject a first element into the blocking gate dielectric layers 172. In some implementations, an annealing process may be performed to inject a first element into the blocking gate dielectric layers 172 and a second element, different from the first element into the gate dielectric layers 162. After the gate electrodes 165 and the blocking gate electrode 175 are formed to completely fill the upper gap regions (UR) and the lower gap regions (LR), the gate dielectric layers 162 and the gate spacer layers 164, and the blocking gate dielectric layers 172 and the blocking gate spacer layers 174 may be removed together from upper portions of the upper gap regions (UR) to a predetermined depth, and gate capping layers 167 and the blocking gate capping layer 177 may be formed in the removed regions. In some implementations, the blocking gate electrode 175 may be formed to include the first element, unlike the gate electrode 165. In some implementations, the blocking gate electrode 175 may be formed to include a first element, and the gate electrodes 165 may be formed to include a second element, different from the first element. Thereafter, an interlayer insulating layer 115 may be further formed on the gate structures 160 and the blocking gate structure 170.

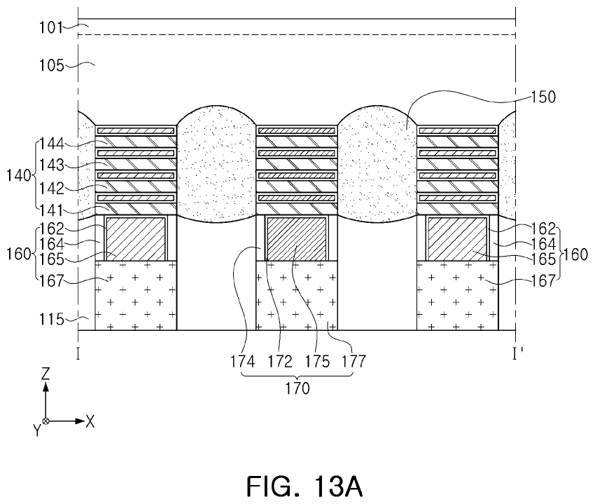

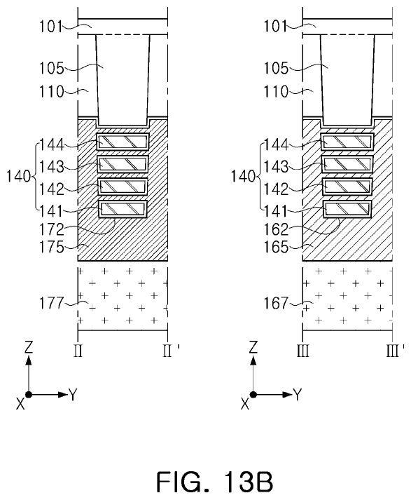

Referring to FIGS. 13A and 13B, a portion of the substrate 101 may be removed.

To perform the process from the lower surface of the substrate 101 of FIGS. 12A and 12B, a separate carrier substrate may be formed on the interlayer insulating layer 115 and the entire structure may be turned over to perform the following processes.

The substrate 101 may be thinned by removing a portion of the substrate, for example, by a lapping, grinding, and/or polishing process. In some implementations, the active region 105 and the element isolation layer 110 may be partially removed.

In this step, only the substrate 101 is partially removed and the active region 105 and the element isolation layer 110 are not removed, or even if the active region 105 and the element isolation layer 110 are partially removed, other components, such as the blocking gate structure 170, are not removed, so that the process difficulty and process cost may be reduced.

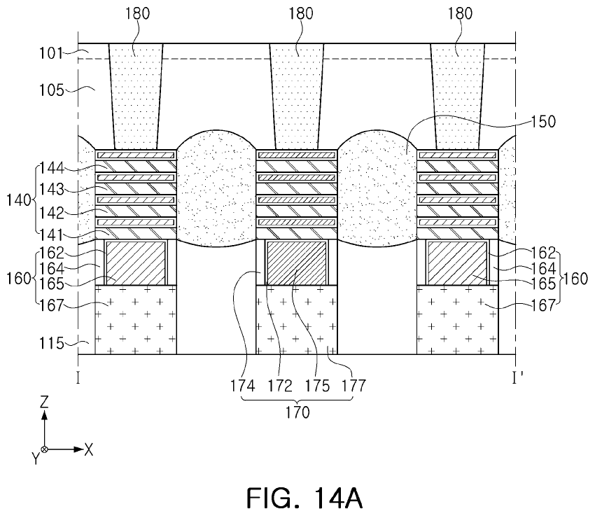

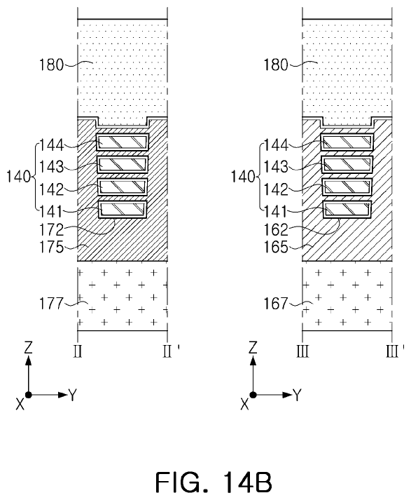

Referring to FIGS. 14A and 14B, backside blocking structures 180 that penetrate the substrate 101 and the active region 105 may be formed.

The backside blocking structures 180 may be formed by forming holes by partially removing the substrate 101 and the active region 105 to expose the gate structures 160 and the blocking gate structure 170, and then depositing an insulating material to fill the holes. In some implementations, when the blocking gate structure 170 is partially recessed to form a hole, a first backside blocking structure 181 such as FIG. 3A may be formed.

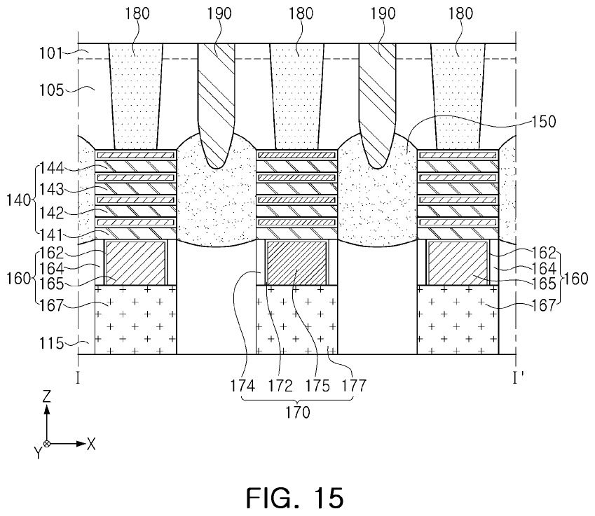

Referring to FIG. 15, backside contact structures 190 penetrating the substrate 101 and the active region 105 may be formed.

The backside contact structures 190 may be formed by forming a contact hole penetrating the substrate 101 and the active region 105 and extending into the interior of the source/drain regions 150, and then filling the interior of the contact hole with a conductive material. When the backside contact structures 190 include a metal-semiconductor compound layer, the metal-semiconductor compound layer may be first formed along the surface of the source/drain regions 150 exposed through the contact hole, and then a conductive layer may be formed to fill the contact hole.

Next, referring to FIGS. 2A and 2B together, a backside insulating layer 194 may be formed on the lower surface of the substrate 101, and may be partially removed to form a backside power structure 195 connected to the backside contact structure 190. As a result, the semiconductor devices of FIGS. 2A and 2B may be manufactured.

As set forth above, according to some example implementations, by utilizing a gate structure constituting a transistor having a threshold voltage higher than an operating voltage of surrounding transistors, as an electrical blocking element together with a backside blocking structure, a semiconductor device with reduced process costs and process difficulty and improved reliability may be provided.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While example implementations have been illustrated and described above, it will be apparent to those skilled in the art that modifications and variations could be made without departing from the scope of the present disclosure as defined by the appended claims.

What is claimed is:

1. A semiconductor device comprising:
a substrate including an active region extending in a first direction;
gate structures extending in a second direction overlapping the active region, on the substrate, and spaced apart from each other in the first direction;
a blocking gate structure overlapping the active region, between the gate structures, and extending in the second direction;
a plurality of channel layers surrounded by the blocking gate structure and the gate structures, respectively, on the active region, and spaced apart from each other in a third direction perpendicular to an upper surface of the substrate;
source/drain regions in portions of the active region that are recessed, wherein the source/drain regions are on both sides of the blocking gate structure, and are connected to the plurality of channel layers;
a first backside contact structure below a first source/drain region, wherein the first backside contact structure extends through the substrate and into the first source/drain region from a lower surface of the first source/drain region, wherein the first backside contact structure is electrically connected to the first source/drain region; and
a plurality of backside blocking structures below the gate structures and the blocking gate structure, respectively, wherein the plurality of backside blocking structures extend through the substrate and the active region, and separate the active region,
wherein the blocking gate structure includes a first element different from the gate structures.

2. The semiconductor device of claim 1, wherein the source/drain regions include silicon and an n-type dopant, and
the first element includes a material configured to shift a threshold voltage of a transistor in a positive direction.

3. The semiconductor device of claim 2, wherein the first element includes at least one of aluminum, tantalum, tungsten, manganese, chromium, ruthenium, platinum, gallium, germanium, and gold.

4. The semiconductor device of claim 3, wherein the blocking gate structure includes:
blocking gate dielectric layers disposed on each the plurality of channel layers;
a blocking gate electrode on the blocking gate dielectric layers; and
a blocking gate capping layer extending in the second direction on the blocking gate electrode,
wherein at least one of the blocking gate dielectric layers and the blocking gate electrode includes the first element.

5. The semiconductor device of claim 1, wherein the source/drain regions include silicon germanium and a p-type dopant, and
the first element includes a material configured to shift a threshold voltage of a transistor in a negative direction.

6. The semiconductor device of claim 5, wherein the first element includes at least one of lanthanum, gadolinium, ruthenium, yttrium, and scandium.

7. The semiconductor device of claim 6, wherein the blocking gate structure includes:
blocking gate dielectric layers on each the plurality of channel layers;
a blocking gate electrode on the blocking gate dielectric layers; and
a blocking gate capping layer extending in the second direction on the blocking gate electrode,
wherein at least one of the blocking gate dielectric layers and the blocking gate electrode includes the first element.

8. The semiconductor device of claim 1, wherein the backside blocking structures include a first backside blocking structure below the blocking gate structure and second backside blocking structures respectively disposed below the gate structures,
wherein the first backside blocking structure extends into the blocking gate structure from below.

9. The semiconductor device of claim 1, wherein the backside blocking structures include a first backside blocking structure below the blocking gate structure and second backside blocking structures respectively disposed below the gate structures,
wherein an upper end of the first backside blocking structure is positioned at a higher level relative to the substrate than upper ends of the second backside blocking structures.

10. The semiconductor device of claim 1, wherein upper ends of the first backside contact structure are positioned at a higher level relative to the substrate than an upper end of the backside blocking structure.

11. The semiconductor device of claim 10, further comprising:
a backside insulating layer covering respective lower surfaces of the substrate, the backside blocking structures, and the first backside contact structure; and
a backside power structure extending into the backside insulating layer and connected to the first backside contact structure.

12. The semiconductor device of claim 11, wherein the backside power structure is spaced apart from the backside blocking structures.

13. The semiconductor device of claim 1, wherein a width of the backside blocking structures is equal to or greater than a width of the active region, in the second direction.

14. A semiconductor device comprising:
a substrate;
a gate structure extending in a first direction on the substrate;
a blocking gate structure adjacent to a first side of the gate structure, on the substrate, and extending in the first direction;
a source/drain region between the gate structure and the blocking gate structure and in contact with the gate structure and the blocking gate structure;
a backside contact structure extending into the substrate, and partially extending into the source/drain region from a lower surface of the source/drain region, wherein the backside contact structure is electrically connected to the source/drain region; and
backside blocking structures comprising
a first backside blocking structure below the blocking gate structure, extending through the substrate and in contact with the blocking gate structure, and
a second backside blocking structure below the gate structure, extending through the substrate and in contact with a lower surface of the gate structure,
wherein a first transistor including the blocking gate structure is configured to exhibit a first threshold voltage, a second transistor including the gate structure is configured to exhibit a second threshold voltage, and wherein an absolute value of the first threshold voltage is greater than an absolute value of the second threshold voltage.

15. The semiconductor device of claim 14, wherein the absolute value of the first threshold voltage is 2 to 4 times the absolute value of the second threshold voltage.

16. The semiconductor device of claim 14, wherein the first threshold voltage and the second threshold voltage have positive values, and
a difference between the first threshold voltage and the second threshold voltage is 0.15 V or more.

17. The semiconductor device of claim 14, wherein the first threshold voltage and the second threshold voltage have negative values, and
a difference between the first threshold voltage and the second threshold voltage is 0.15 V or more.

18. A semiconductor device comprising:
a substrate having a first region and second regions;
a plurality of gate structures on the substrate;
a plurality of source/drain regions, wherein each source/drain region is between adjacent gate structures of the plurality of gate structures; and
a plurality of backside blocking structures below the plurality of gate structures, respectively, wherein the plurality of backside blocking structures extend through the substrate, and contact the plurality of gate structures, respectively,
wherein the plurality of gate structures include
first gate structures spaced apart from each other in a first direction, on the first region, and extending in a second direction intersecting the first direction,
second gate structures spaced apart from each other in the first direction and extending in the second direction, on the second region,
a first blocking gate structure between the first gate structures, on the first region, and
a second blocking gate structure between the second gate structures, on the second region,
wherein the first gate structures and the second blocking gate structure include a first element, and
the second gate structures and the first blocking gate structure include a second element that is different from the first element.

19. The semiconductor device of claim 18, wherein the first gate structures form N-type transistors, and the second gate structures form P-type transistors,
the first element is at least one of aluminum, tantalum, tungsten, manganese, chromium, ruthenium, platinum, gallium, germanium, and gold, and
the second element is at least one of lanthanum, gadolinium, ruthenium, yttrium, and scandium.

20. The semiconductor device of claim 18, further comprising a first backside contact structure below a first source/drain region among the plurality of source/drain regions, wherein the first backside contact structure extends through the substrate and partially extends into the first source/drain region from a lower surface of the first source/drain region.
